(19) United States
(12) Patent Application Publication
(10) Pub. No.: US 2025/0132742 A1
(43) Pub. Date: Apr. 24, 2025

(54) OPTIMIZED CONTROL CIRCUIT FOR A MICROELECTROMECHANICAL SOUND GENERATOR AND A SOUND GENERATION SYSTEM

(71) Applicant: Robert Bosch GmbH, Stuttgart (DE)

(72) Inventors: Guido De Sandre, Brugherio (IT); Raik Fiedler, Peitz (DE)

(21) Appl. No.: 18/887,599

(22) Filed: Sep. 17, 2024

(30) Foreign Application Priority Data
Oct. 18, 2023 (DE) 10 2023 210 188.2

(51) Int. Cl. H03F 3/45; B81B 3/00; H03F 1/02

(52) U.S. Cl. CPC H03F 3/45668; B81B 3/0086; H03F 1/0227; B81B 2201/0257; H03F 2200/03; H03F 2200/78

(57) ABSTRACT

A control circuit for a microelectromechanical sound generator with a first center connector, a second center connector, a first external connector, and a second external connector. The control circuit includes a differential amplifier which comprises a first output connector coupled to the first external connector and a second output connector coupled to the second external connector and is configured to control the first external connector and the second external connector with a differential signal that corresponds to an input signal. The control circuit includes a first voltage generator circuit, which is configured to provide the first center connector with a predetermined first DC voltage in relation to a common-mode voltage of the differential amplifier, and a second voltage generator circuit, which is configured to provide the second center connector with a predetermined second DC voltage in relation to the common-mode voltage of the differential amplifier.

### CROSS REFERENCE

The present application claims the benefit under 35 U.S.C. § 119 of German Patent Application No. DE 10 2023 210 188.2 filed on Oct. 18, 2023, which is expressly incorporated herein by reference in its entirety.

### FIELD

The present invention relates to an optimized control circuit for a microelectromechanical sound generator and a corresponding sound generation system. The present invention relates in particular to a control of a microelectromechanical sound generator with a plurality of center connectors.

### BACKGROUND INFORMATION

Sound generators can be used in loudspeakers, earphones or other devices to generate sound waves from an electrical signal. With increasing miniaturization, sound generation elements based on microelectromechanical systems (MEMS), too, are becoming more and more important. There are sound generators, for instance, in which a membrane can be excited by means of electrostatic forces.

European Patent Application No. EP 2 582 156 A2 describes an electrostatic loudspeaker that can be embodied as MEMS, for example. In one approach, it has been proposed that an audio signal be conducted to external capacitor plates using a differential amplifier, see FIG. 1, in order to drive a microelectromechanical sound generator.

### SUMMARY

The present invention provides an optimized control circuit for a microelectromechanical sound generator and a corresponding sound generation system.

Preferred example embodiments of the present invention are disclosed herein.

According to a first aspect, the present invention relates to a control circuit for a microelectromechanical sound generator. According to an example embodiment of the present invention, the control circuit includes a first center connector, a second center connector, a first external connector and a second external connector. The control circuit includes a differential amplifier which comprises a first output connector coupled to the first external connector and a second output connector coupled to the second external connector and is configured to control the first external connector and the second external connector with a differential signal that corresponds to an input signal. The control circuit comprises a first voltage generator circuit, which is configured to provide the first center connector with a predetermined first DC voltage in relation to a common-mode voltage of the differential amplifier, and a second voltage generator circuit, which is configured to provide the second center connector with a predetermined second DC voltage in relation to the common-mode voltage of the differential amplifier.

According to one further development of the present invention, the control circuit is configured to set a supply voltage for the differential amplifier as a function of a maximum amplitude of the input signal.

According to one further development of the present invention, the control circuit comprises a level converter which is configured to adjust a common-mode signal level of the input signal, wherein the level converter is coupled to or integrated in the differential amplifier in order to provide the adjusted input signal.

According to one further development of the present invention, the control circuit is configured to receive a supply voltage for the level converter as a function of a maximum amplitude of the input signal.

According to one further development of the present invention, the control circuit is configured to receive an electrical voltage between a reference potential and a predetermined positive supply voltage as the supply voltage for the differential amplifier.

According to one further development of the present invention, the control circuit is configured to receive an electrical voltage between a predetermined negative supply voltage and a predetermined positive supply voltage as the supply voltage for the differential amplifier.

According to one further development of the present invention, the differential amplifier is embodied as a class G amplifier or a class H amplifier.

According to one further development of the present invention, the first voltage generator circuit provides the predetermined first DC voltage in relation to the common-mode voltage of the differential amplifier via a first buffer circuit. The first buffer circuit preferably uses two supply voltages, the voltage difference of which is kept constant by a first potential-free charge pump (see left part of FIG. 5), preferably by using a first comparator which compares two currents; for example a first current, the comparison current, that is proportional to the voltage difference between the supply voltages, and a second current, the reference current, that is proportional to a reference voltage.

According to one further development of the present invention, the second voltage generator circuit provides the predetermined second DC voltage in relation to the common-mode voltage of the differential amplifier via a second buffer circuit. The second buffer circuit preferably uses two supply voltages, the voltage difference of which is kept constant by a second potential-free charge pump (see left part of FIG. 6), preferably by using a first comparator which compares two currents; for example a first current, the comparison current, that is proportional to the voltage difference between the supply voltages, and a second current, the reference current, that is proportional to a reference voltage.

According to one further development of the present invention, the control circuit comprises a signal processing device which is configured to receive a digital audio signal, convert the digital audio signal into an analog audio signal, and provide the analog audio signal as an input signal to the level converter or the differential amplifier. The signal processing device can further be configured to ascertain the maximum amplitude of the input signal using the digital input signal.

According to one further development of the present invention, the signal processing device is configured to process the digital signal using a digital signal processor and then convert it into an analog audio signal.

According to a second aspect, the present invention relates to a microelectromechanical sound generator comprising a first center connector, a second center connector, a first external connector and a second external connector, wherein the first external connector is disposed on a first substrate of the microelectromechanical sound generator and the second external connector is disposed on the first substrate, and wherein the first center connector is disposed on a second substrate of the microelectromechanical sound generator and the second center connector is disposed on the second substrate.

According to one further development of the present invention, the first substrate is configured to reduce a parasitic capacitance between the first external connector and the first substrate and a parasitic capacitance between the second external connector and the first substrate, and/or the second substrate is configured to increase a parasitic capacitance between the first center connector and the second substrate and a parasitic capacitance between the second center connector and the second substrate.

According to one further development of the present invention, the first substrate is static and the second substrate is movable, or the first substrate is movable and the second substrate is static.

According to a third aspect, the present invention relates to a sound generation system comprising a control circuit and a microelectromechanical sound generator as described above.

The present invention is based, among other things, on the insight that the control of a sound generator based on a MEMS with an electrostatically controllable membrane typically requires electrical voltages that exceed the voltage level of conventional CMOS technology. The control of such sound generators therefore requires a suitable control circuit that can provide electrical voltages at a sufficient voltage level. The energy requirement of conventional control circuits can therefore be high. Conventional control circuits may also not be able to control a sound generator comprising a plurality of center connectors efficiently.

It is therefore an object of the present invention to create an efficient control for electrostatic sound generators comprising a plurality of center connectors which have a reduced energy requirement.

For this purpose, it is provided on the one hand to raise the electrical voltage level by means of a bias voltage through a voltage generator circuit. Moreover, in analogy to a class H amplifier, the supply voltage for a differential amplifier provided in the control circuit can be adjusted as a function of the respective current signal amplitude. This can take advantage of the fact that sound signals typically only very rarely have a high, in particular a maximum, amplitude. During long phases of low signal amplitudes, the differential amplifier can be operated with a lower supply voltage. This results in a significantly lower energy requirement. In particular in battery-operated systems, this makes it possible to increase the operating time per battery charge significantly.

In principle, any suitable differential amplifier circuit in the form of discrete components or integrated circuits that is capable of providing an amplified output signal corresponding to an input signal and can be operated with a variable supply voltage can be used as a differential amplifier. As will be explained in more detail in the following, the differential amplifier can be operated with a supply voltage between a reference potential (0 volts) and a (positive) supply voltage or, in alternative embodiments, also with a negative and a positive supply voltage.

### BRIEF DESCRIPTION OF THE DRAWINGS

Further features and advantages of the present invention are explained in the following with reference to the figures.

FIG. 1 shows a schematic illustration of a control circuit and a microelectromechanical sound generator comprising a center connector, according to an example embodiment of the present invention.

FIG. 2 shows a schematic illustration of a control circuit and a microelectromechanical sound generator comprising a plurality of center connectors according to one example embodiment of the present invention.

FIG. 3 shows a schematic illustration of a control circuit for a microelectromechanical sound generator according to one example embodiment of the present invention.

FIG. 4 shows a schematic illustration of the example of a microelectromechanical sound generator of FIG. 2 according to one example embodiment of the present invention.

FIG. 5 shows a schematic illustration of a charge pump for a control circuit according to one example embodiment of the present invention.

FIG. 6 shows a schematic illustration of a charge pump for a control circuit according to one example embodiment of the present invention.

FIG. 7 shows schematic illustrations of comparators for the charge pumps of FIG. 5 and FIG. 6 according to one example embodiment of the present invention.

FIG. 8 shows a schematic illustration of a circuit for generating a comparison current in a high voltage range for a control circuit according to one example embodiment of the present invention.

FIG. 9 shows a schematic illustration of a circuit for generating a reference current in a low voltage range for a control circuit according to one example embodiment of the present invention.

FIG. 10 shows schematic illustrations of a circuit for generating a reference current in a low voltage range for a control circuit according to one example embodiment of the present invention.

FIG. 11 shows schematic illustrations of a circuit for generating a comparison current in a high voltage range for a control circuit according to one example embodiment of the present invention.

FIG. 12 shows schematic illustrations of a current subtractor for a control circuit according to one example embodiment of the present invention.

FIG. 13 shows schematic illustrations of a current subtractor for a control circuit according to one example embodiment of the present invention.

FIG. 14 shows schematic illustrations of a current comparator for a control circuit according to one example embodiment of the present invention.

FIG. 15 shows operating characteristics of the current comparator of FIG. 14.

FIG. 16 shows schematic illustrations of a current comparator for a control circuit according to one example embodiment of the present invention.

FIG. 17 shows operating characteristics of the current comparator of FIG. 16.

FIG. 18 shows schematic illustrations of a current comparator for a control circuit according to one example embodiment of the present invention.

FIG. 19 shows operating characteristics of the current comparator of FIG. 18.

In all figures, identical or functionally identical elements and apparatuses are provided with the same reference sign.

### DETAILED DESCRIPTION OF EXAMPLE EMBODIMENTS

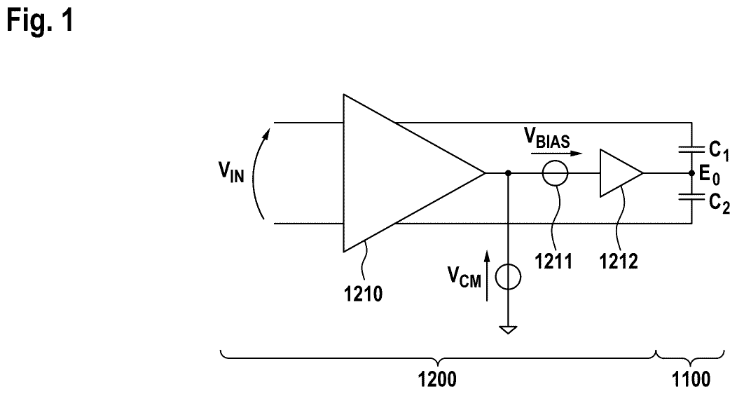

FIG. 1 shows a schematic illustration of a control circuit 1200 and a microelectromechanical sound generator 1100 comprising a center connector E₀.

In this sound generation system, sound can be generated by means of the microelectromechanical sound generator 1100, for instance. A membrane of the microelectromechanical sound generator 1100 can be deflected by providing sufficiently high electrical voltages. In FIG. 1, the microelectromechanical sound generator 1200 is represented by the two capacitors C₁ and C₂ which are electrically connected to one another via a single center connector E₀. The respective other connectors of the capacitors C₁ and C₂ form the external connectors of the microelectromechanical sound generator 1100.

To control the microelectromechanical sound generator 1100, an input signal V_{IN} can be amplified by means of a differential amplifier 1210. The two output connectors of the differential amplifier 1210 can be electrically connected to the external connectors of the microelectromechanical sound generator 1100. To provide a sufficiently high electrical voltage to deflect the membrane of the microelectromechanical sound generator 1100, an electrical voltage is provided at the center connector E₀ which is increased relative to the common-mode voltage V_{C} of the differential amplifier 1210 by a bias voltage V_{BIAS}. For this purpose, a voltage generator circuit 1211 can be provided in the control circuit 1200 with the differential amplifier 1210. The thus increased common-mode voltage can be fed to the center connector E₀ via a buffer circuit 1212 if necessary.

The control circuit 1200 has to be dimensioned such that even the maximum expected amplitudes of the input signal V_{IN} can be amplified with sufficient quality in accordance with the requirements. To amplify signals with the maximum expected amplitude in the input signal V_{IN}, a correspondingly high supply voltage has to be provided on the differential amplifier 1210.

In practice, the mechanical movements of the capacitor plates of the microelectromechanical sound generator 1100 shown in FIG. 1 can cause a change in capacitance over time, which can result in a current load on the center connector, because the changes in the upper and lower capacitors can have opposite signs.

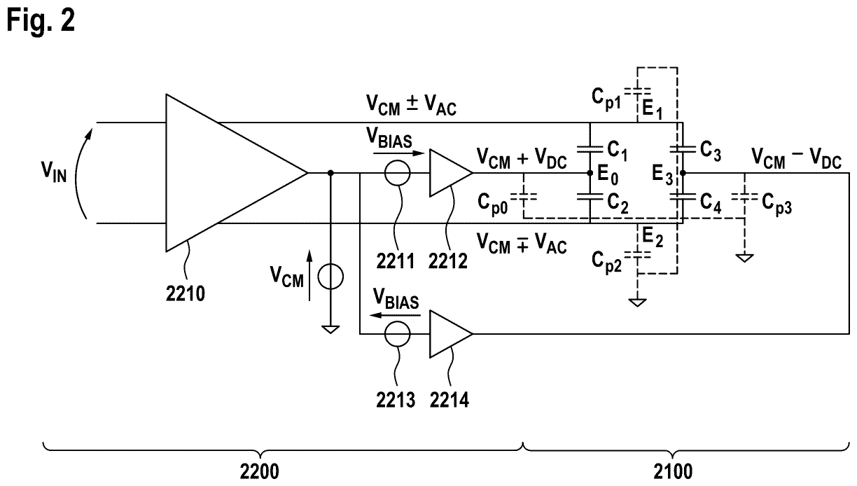

FIG. 2 shows a schematic illustration of a control circuit 2200 and a microelectromechanical sound generator 2100 comprising a plurality of center connectors E₀ and E₃ according to one embodiment.

In this sound generation system, sound can be generated by means of the microelectromechanical sound generator 2100, for instance. The membrane of the microelectromechanical sound generator 2100 can be deflected by providing a sufficiently high electrical voltage. In FIG. 2, the microelectromechanical sound generator 2200 is represented by the capacitors C₁, C₂, C₃ and C₄. The capacitors can be electrically connected to one another in pairs via a center connector. The parasitic capacitors Cₚ₀, Cₚ₁, Cₚ₂ and Cₚ₃ are described in detail with reference to FIG. 4.

As shown in FIG. 2, the capacitors C₁ and C₂ can be electrically connected to one another via a first center connector E₀, while the capacitors C₃ and C₄ are electrically connected to one another via a second center connector E₃.

The other connectors of the capacitors C₁ and C₃ can be electrically connected to one another via a first external connector E₁. The other connectors of the capacitors C₂ and C₄ can be electrically connected to one another via a second external connector E₂.

To control the microelectromechanical sound generator 2100, an input signal V_{IN} can be amplified by means of a differential amplifier 2210. The two output connectors of the differential amplifier 2210 can be electrically connected to the external connectors of the microelectromechanical sound generator 2100.

In FIG. 2, two electrodes are controlled by a respective amplified audio signal, while the other two are controlled by a respective constant voltage. The first external connector E₁ and the second external connector E₂ are controlled by a differential signal with a differential amplitude 2V_{AC} and a common-mode voltage V_{CM}. The first center connector E₀ is controlled by a constant voltage V_{CM}+V_{DC}. The second center connector E₃ is controlled by a constant negative voltage V_{CM}−V_{DC}. V_{CM} is less than V_{DC}, and V_{CM}, V_{AC}, and V_{DC} are all positive numbers. V_{AC} can be approximately about 20 V, for example, while V_{DC} can be approximately about 30V, for example.

A first voltage generator circuit 2211 to increase the common-mode voltage V_{CM} and to supply the increased voltage V_{CM}+V_{DC} to the first center connector E₀ via an optional first buffer circuit 2212 can be provided in the control circuit 2200. A second voltage generator circuit 2213 to reduce the common-mode voltage V_{CM} and to supply the reduced voltage V_{CM}−V_{DC} to the second center connector E₀ via an optional second buffer circuit 2214 can be provided in the control circuit 2200 as well.

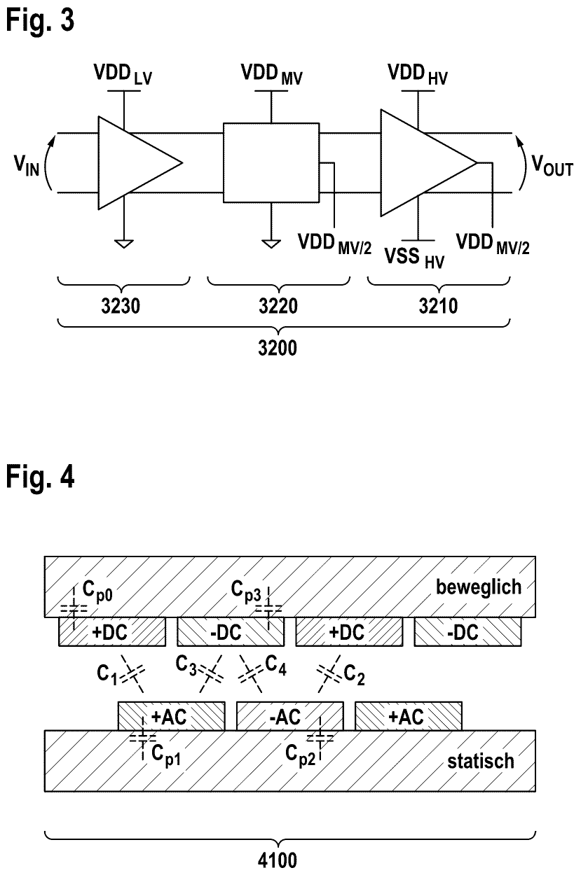

The audio input signal is usually in the low voltage range. Its common mode has to be shifted to a level that matches the common-mode voltage V_{CM} of the differential amplifier. This function can be implemented in a circuit as shown in FIG. 3, for example. This function can alternatively, or at least in part, also be integrated directly into the differential amplifier 2210.

High-pass and/or low-pass filtering and/or buffering of the audio signal can be implemented in a device or not implemented in the device if the respective function is implemented elsewhere in the signal path.

FIG. 3 shows a schematic illustration of a control circuit 3200 for a microelectromechanical sound generator (not shown, see FIG. 2 or FIG. 4, for example) according to one embodiment.

The (analog) input signal V_{IN} can first be fed to a filter 3230, for example, in particular a low-pass filter, possibly with suitable buffering. This filter device 3230 can be operated with a low supply voltage VDD_{LV}. The output signal of these filter devices 3230 can then be fed to a level converter 3220.

The level converter 3220 can raise the signal provided by the filter devices 3230 by a DC voltage component, for example, so that the output signal provided by the level converter 3220 is suitable for being amplified by the downstream differential amplifier 3210 in the corresponding voltage range. The level converter 3220 can be operated with a supply voltage VDD_{MV}, which is usually between the supply voltage VDD_{LV} of the filter device 3230 and the supply voltage VDD_{HV} of the differential amplifier 3210. For example, the voltage level of the input signal V_{IN} can be raised to such an extent that the raised signal does not contain any signal components with a negative voltage, i.e. less than 0 volts.

The signal output by the level converter 3220 can be amplified by the differential amplifier 3210 and fed to a microelectromechanical sound generator such as described with reference to FIG. 2.

The differential amplifier 3210 and the level converter 3220 can always be configured for the maximum expected amplitude of the input signal V_{IN}. The input voltages of the differential amplifier 3210 and the level converter 3220 can accordingly also be provided with sufficient safety reserves corresponding to the amplitude of the input signal V_{IN}.

Since a maximum expected amplitude can rarely occur in the input signal V_{IN} for sound signals, for signal portions with a lower amplitude it can be sufficient to operate the differential amplifier 3210 and, if applicable, the level converter 3220 with a lower supply voltage during these signal portions. According to the present invention, it can therefore be provided that the supply voltages VDD_{HV} and VSS_{HV} of the differential amplifier 3210 and possibly also the supply voltage VDD_{MV} of the level converter 3220 be adjusted in accordance with the current amplitude of the input signal V_{IN}, and, in particular in portions with low amplitude in the input signal V_{IN}, that the supply voltages VDD_{HV} and VSS_{HV} and, if applicable, VDD_{MV} be lowered.

In order to adjust the supply voltages VDD_{MV} and VDD_{HV} and VSS_{HV} to the respective signal amplitude in a timely manner, the input signal V_{IN} can be analyzed on the basis of a digital signal, for instance, before this digital signal is converted into an analog input signal V_{IN}.

The supply voltages for the level shifting function by the level converter 3220 can expediently be at an intermediate voltage level VDD_{MV}, for example at 5V, which is compatible with the common-mode voltage at the amplifier input. The common-mode voltage of the amplifier output V_{CM} can have any value between ground and VDD_{MV}, but can expediently be set at VDD_{MV/2}. The supply voltages VDD_{HV} and VSS_{HV} of the differential amplifier 3210 can be set symmetrically to the common-mode voltage of the amplifier output V_{CM}.

It is possible to use ground and VDD_{MV} within the differential amplifier 3210 as intermediate supplies. The differential amplifier 3210 can thus be embodied as a class G amplifier. The high voltage supplies VDD_{HV} and VSS_{HV} can be increased or reduced depending on the input signal, however, thus realizing a class H amplifier.

If the audio signal is small, e.g. 20 dB below the maximum, it is possible to reduce VDD_{HV} to VDD_{MV} and VSS_{HV} to ground, as a result of which the differential amplifier 3210 is operated in a reduced voltage range and can have a significantly lower power consumption.

One advantage of aspects of the control circuit 3200 is that the power required for buffering to keep the first center connector E₀ and the second center connector E₃ at a respective constant voltage is negligible in the first order. Strictly speaking, this would be true if the capacitors remained linear and unchanging over time. This hypothesis is not entirely true if there is a large amount of mechanical movement and the buffering has to be able to support some current load. However, aspects of the control circuit 3200 are capable of minimizing current loads under certain symmetry conditions in a MEMS.

FIG. 4 shows a schematic illustration of the example of a sound generator 4100 of FIG. 2 according to one embodiment. The capacitors C₁, C₂, C₃ and C₄ of FIG. 3 and also the parasitic capacitors Cₚ₀, Cₚ₁, Cₚ₂ and Cₚ₃ are identified inside the sound generator 4100 in FIG. 4.

FIG. 4 shows the structure of the capacitors used for electrostatic drive of the sound generator 4100. For the sake of simplicity, the V_{CM} component has been omitted from the electrode voltages shown in FIG. 4. From FIG. 4 it can be seen that the parasitic capacitors Cₚ₀ and Cₚ₃ can have a common connector and that the parasitic capacitors Cₚ₁ and Cₚ₂ can also have a common connector.

As described in detail in the following, the current load for the buffering can be reduced under the condition C₁=C₂=C₃=C₄ and Cₚ₀=Cₚ₃, for example. If the voltage at the first external connector E₁ rises and the voltage at the second external connector E₂ falls, the capacitances C₁ and C₄ decrease while the capacitances C₂ and C₃ increase. There is therefore a net current flow from the first center connector E₀ to the second center connector E₃. The first center connector E₀ tends to decrease its voltage, while the second center connector E₃ tends to increase its voltage. The series of parasitic capacitors Cₚ₀ and Cₚ₃ supplies a charge to the first center connector E₀ while the second center connector E₃ is discharged. Given their beneficial effect, the capacitors Cₚ₀ and Cₚ₃ should be large in size, although requirements for the bandwidth of the buffering can set a limit.

According to one particular aspect, the substrate of the first center connector E₀ and the second center connector E₃, i.e. the common connector of Cₚ₀ and Cₚ₃, can be biased with a relatively high impedance, while the two capacitors still behave like two separately grounded capacitors and not as a series of the capacitors.

The capacitors Cₚ₁ and Cₚ₂ should be as small as possible to reduce the power consumption of the differential amplifier.

If, with reference to FIG. 4, the electrodes on the movable part of the sound generator 4100 are controlled with ±V_{AC} voltages and the electrodes on the static part of the sound generator 4100 are controlled with ±V_{DC} voltages, the schema is still applicable. It is then sufficient to assign the first center connector E₀ to the electrode controlled with +V_{DC} (+V_{CM}), the second center connector E₃ to the electrode controlled with −V_{DC} (+V_{CM}) and the external connectors E₁ and E₂ with the electrodes controlled with ±V_{AC}.

In this newly assigned configuration, the parasitic capacitors Cₚ₁ and Cₚ₂ take on the role of Cₚ₀ and Cₚ₃ and have to be renamed Cₚ₀ and Cₚ₃. Conversely, the parasitic capacitors Cₚ₀ and Cₚ₃ take on the role of Cₚ₁ and Cₚ₂ and have to be renamed Cₚ₁ and Cₚ₂.

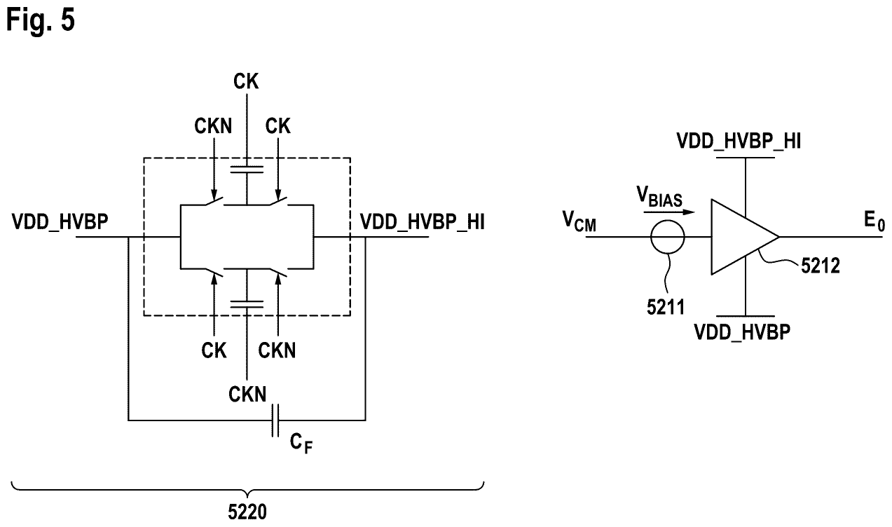

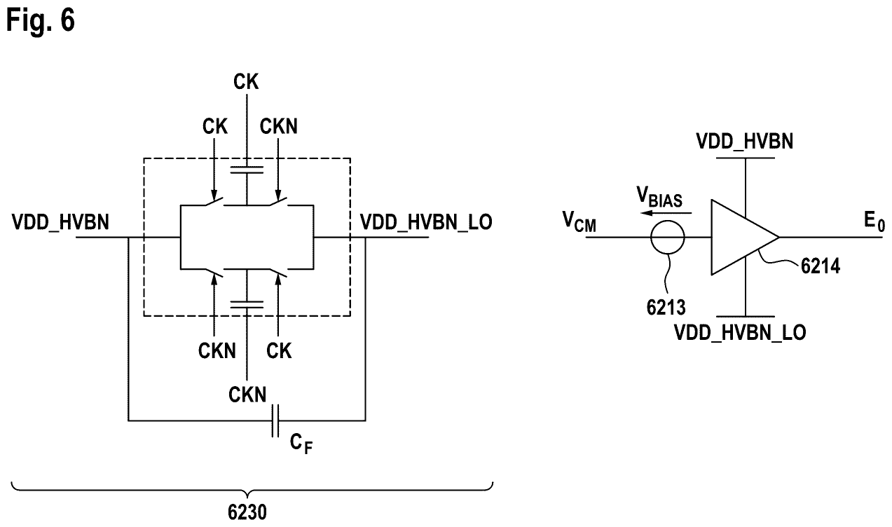

The buffering consumes a certain amount of bias current to ensure a certain bandwidth. The buffering can be powered by two voltage rails that have a voltage difference lower than VDD_{MV}, e.g. 2 V or up to 5 V, preferably 4 V. Such a voltage difference can be created by potential-free charge pumps as shown schematically in FIGS. 5 and 6.

The buffering that controls the first center connector E₀ uses VDD_HVBP as the low supply voltage and VDD_HVBP_HI as the high supply voltage. The bias current flows from the high voltage to the lower voltage, which reduces the voltage difference between the two nodes VDD_HVBP_HI and VDD_HVBP. By means of a comparator, the potential-free charge pump can detect when a difference VDD_HVBP_HI−VDD_HVBP becomes smaller than a predetermined threshold value, e.g. 2 V. If the difference falls below the threshold value, a pumping process starts in order to bring the voltage difference above the threshold value.

The buffering that controls the second center connector E₃ uses VDD_HVBN as the high supply voltage and VDD_HVBN_LO as the low supply voltage. The bias current flows from the high voltage to the lower voltage, which reduces the voltage difference between the two nodes VDD_HVBN and VDD_HVBN_LO. By means of a comparator, the potential-free charge pump can detect when a difference VDD_HVBN−VDD_HVBN_LO becomes smaller than a predetermined threshold value, e.g. 2 V. If the difference falls below the threshold value, a pumping process starts in order to bring the voltage difference above the threshold value.

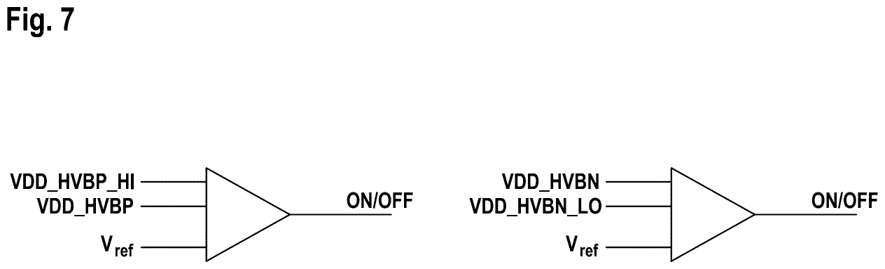

FIG. 7 shows schematic illustrations of comparators that can be used for the charge pumps of FIG. 5 and FIG. 6 according to one embodiment. The shown comparators implement the comparison functions VDD_HVBP_HI−VDD_HVBP>γ V_{ref}, where γ V_{ref}=2 V can apply, for example, and VDD_HVBN−VDD_HVBN LO>γ V_{ref}, where γ V_{ref}=2 V can apply.

Based on the comparison, an ON or an OFF signal is generated for each potential-free charge pump.

A variety of solutions can be used to implement the desired functions of creating a voltage difference and comparing said difference with another voltage reference. For example, it is possible to use standard differential amplifiers and comparators, followed by dedicated analog level shifters to either shift the voltage differences to a low voltage range and carry out the comparison there, or by shifting the reference voltage V_{ref} to a high voltage range of the potential-free comparators. However, these implementations may be less advantageous in terms of their surface area and/or power consumption.

For the intended application, a different approach for generating a supply voltage differential signal and an analog level shift is presented. The level shift can preferably be toward the low voltage range in order to control a clock control circuit, which also operates in the low voltage range, for each charge pump with the ON or OFF signals.

A comparison current, which is proportional to the voltage difference between the supply voltages of the potential-free charge pumps, and a reference current, which is proportional to a reference voltage, are generated. The comparison current generated in a high voltage range can be shifted to a low voltage range where it is compared with the reference current.

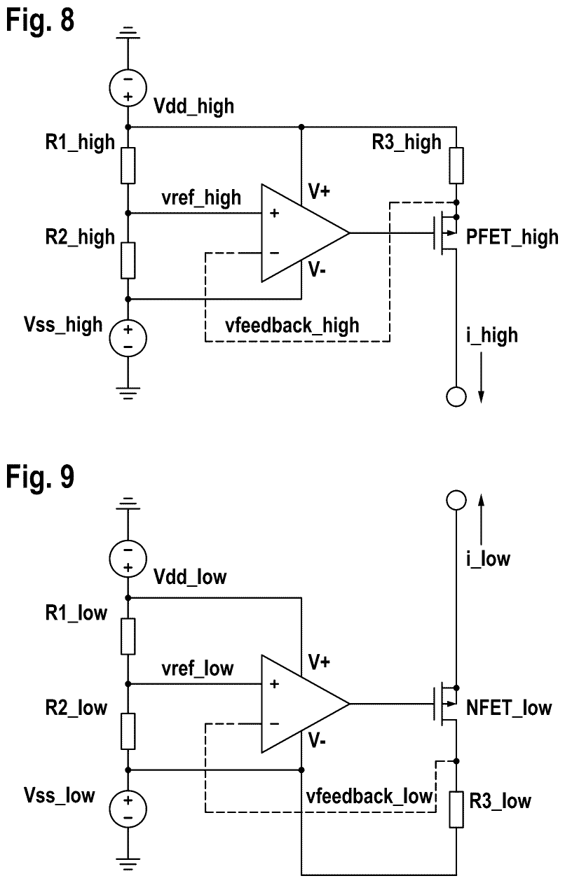

FIG. 8 shows a schematic illustration of a circuit for generating a current in a high voltage range for a control circuit according to one embodiment. A voltage divider with fixed resistances R1_high and R2_high generates a reference voltage vref_high as a function of the ratio of the supply voltage Vdd_high to Vss_high, which corresponds to the abovementioned supply voltages VDD_HVBP_HI and VDD_HVBP.

This voltage is then used in combination with a standard operational amplifier, which can only operate in the local voltage range and does not need to see high voltages, to bias PFET_high such that the same current that flows through R1_high also flows through R3_high. R1_high and R3_high thus have the same fixed resistance, while R2_high can be selected with a very high impedance in order to achieve low current consumption. In this circuit, the current i_high corresponds to the actual voltage difference between the potential-free supply voltages Vdd_high and Vss_high.

A complementary circuit in which the roles of Vdd_high and Vss_high are reversed and the PFET is replaced by an NFET could be used in the high negative voltage range. In this case, Vdd_high and Vss_high correspond to VDD_HVBN and VDD_HVBN_LO respectively.

FIG. 9 shows a schematic illustration of a circuit for generating a reference current in a low voltage range for a control circuit according to one embodiment. A similar approach can be used for the low voltage range to generate a reference for further comparison. The mode of operation of the circuit is analogous to the mode of operation as described with reference to FIG. 8. The resistances R2_low and R3_low have the same resistance values and can also be the same as R1_high and R3_high. R1_low can be selected with a very high impedance in order to achieve low current consumption and can be the same as R2_high.

Two separate circuits, such as those shown in FIG. 8, can be used for the two potential-free comparators in the high voltage range. This enables a difference in the respective supply rails to be converted into a current and shifted to the low voltage range much more easily and with less current consumption. A reference current is also generated in the low voltage range and can be used instead of the aforementioned reference voltage Vref. However, other variations for generating a reference current in the voltage ranges are possible as well.

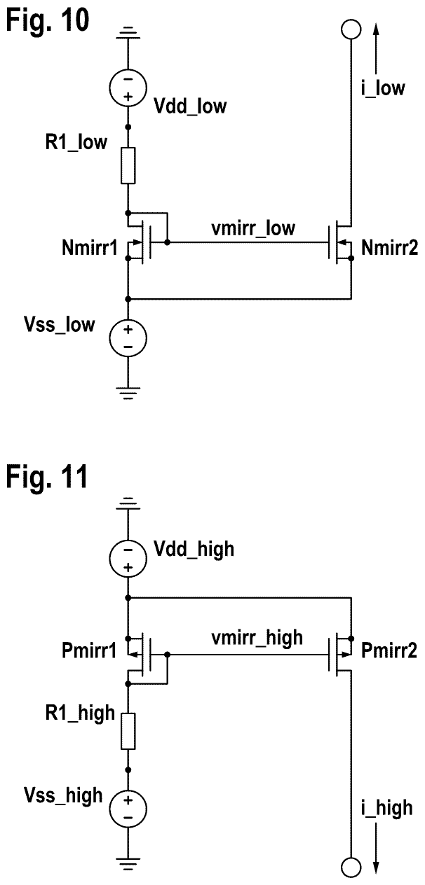

FIG. 10 shows an example of how a circuit in which an NFET current mirror and a resistance R1_low with a fixed high impedance can be used to generate a reference current. FIG. 11 shows an example of how a circuit in which a PMOS current mirror and a resistance R1_high with a fixed high impedance can use to generate a current.

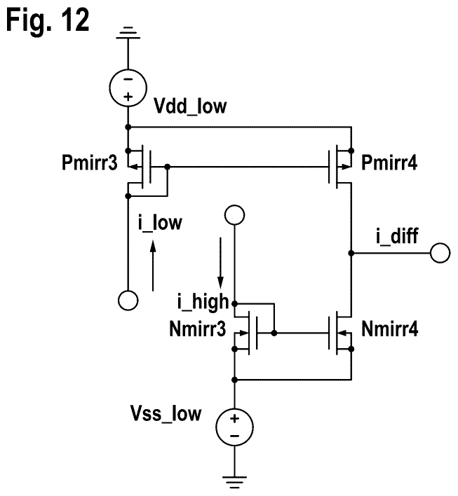

The currents that represent the differences in the supply lines can be used to carry out a comparison operation. Providing currents makes it possible to use a simple current subtractor as shown in FIG. 12.

The reference current i_low from the low voltage range can be mirrored on the same path as the corresponding current i_high from the potential-free high voltage domain, wherein the two converge to i_diff. Assuming a constant mirror ratio of 1:1 for all circuits, the voltage at i_diff changes as a function of the resulting current difference i_low−i_high.

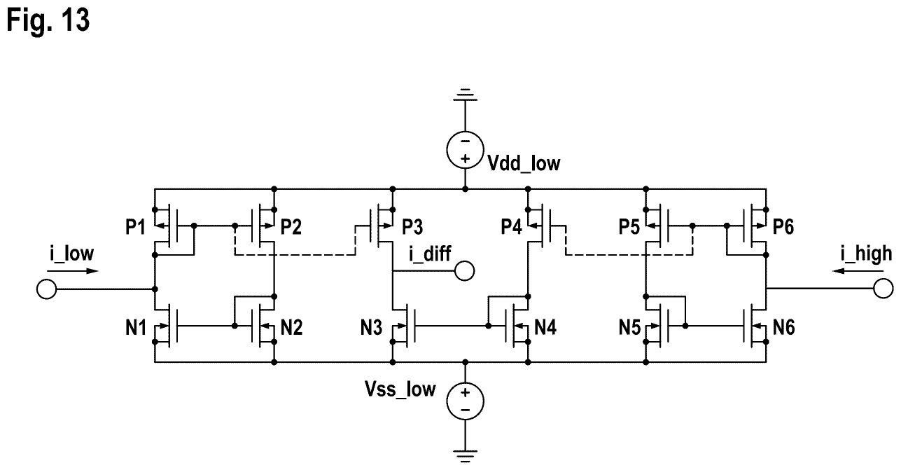

FIG. 13 shows a more advanced current subtractor that also implements this function. Here, the currents from the two voltage ranges are first decoupled from the outside by self-amplifying current mirrors P1, P2, N1 and N2 for i_low and P5, P6, N5 and N6 for i_high. The currents coming from the outside set a stable operating point. These buffered currents can then be subtracted as described with reference to FIG. 12 in order to again obtain a corresponding voltage at i_diff.

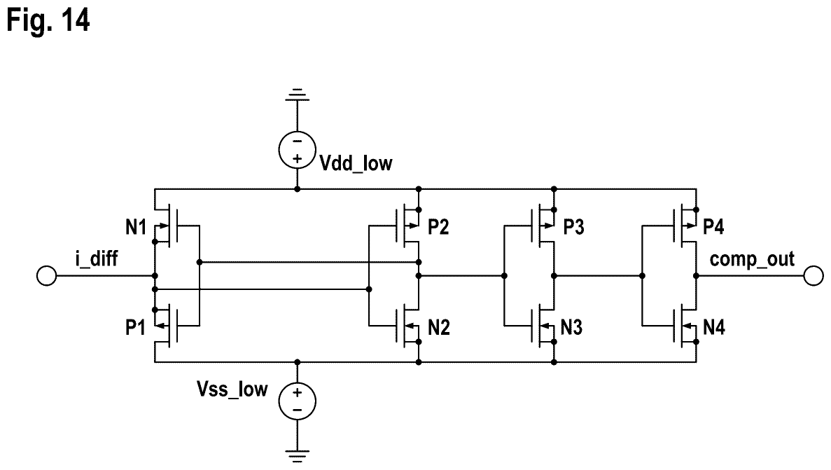

The voltage at i_diff has to now be converted into a logical signal that represents the desired ON and OFF functionality for the clock control and thus for the charge pump and the potential-free supply rails themselves. Three different implementations of a current comparator are shown and described in the following with reference to FIGS. 14 to 19.

FIG. 14 shows a current comparator with a cross-coupled inverter input stage in which N1 and P1 are reversed from their default positions. In this configuration, the potential i_diff is kept close to the switching threshold of this inverter configuration. When the current at i_diff is changed by the above-described current subtractor, the input voltage for the next inverter P3/N3 changes so slightly that it exceeds the switching threshold and leads to a change in the potential at comp_out from low to high or from high to low.

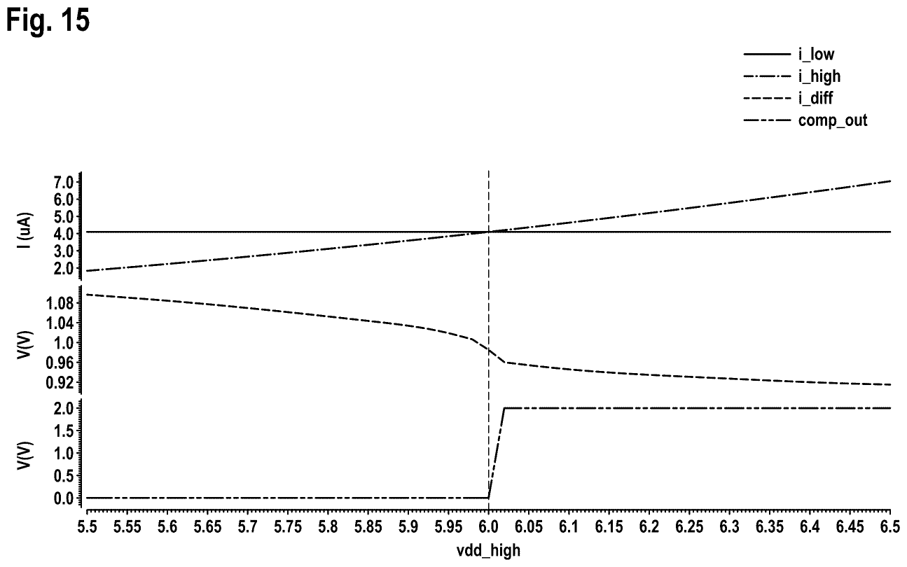

FIG. 15 shows the mode of operation of the current comparator in FIG. 14. By changing the Vdd_high potential from 5.5 V to 6.5 V (Vss_high is stable at 4 V), the current i_high changes linearly, while the current i_low in the low voltage range is kept stable by not changing the low voltage supply Vdd_low=2 V (Vss_low=0 V). Both supply ranges produce the same current at a potential difference of 2 V. The voltage at the current subtractor at i_diff also changes accordingly. In the shown implementation, the resulting signal comp_out remains logically low if i_high is less than i_low and switches to logically high as soon as i_high is greater than i_low.

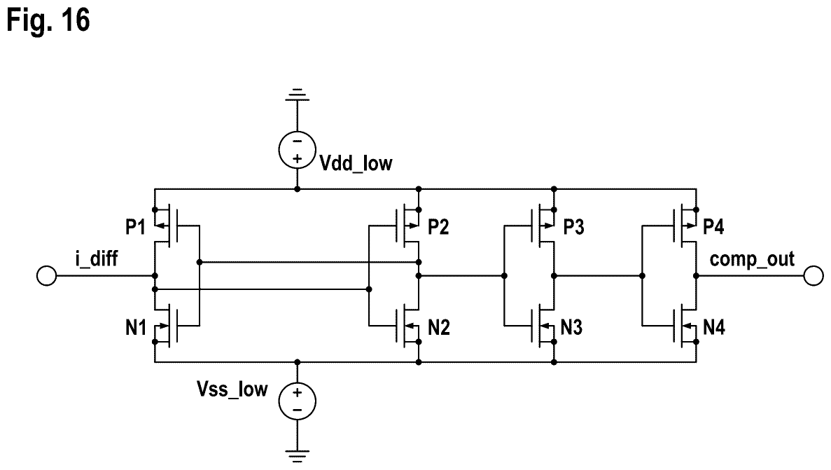

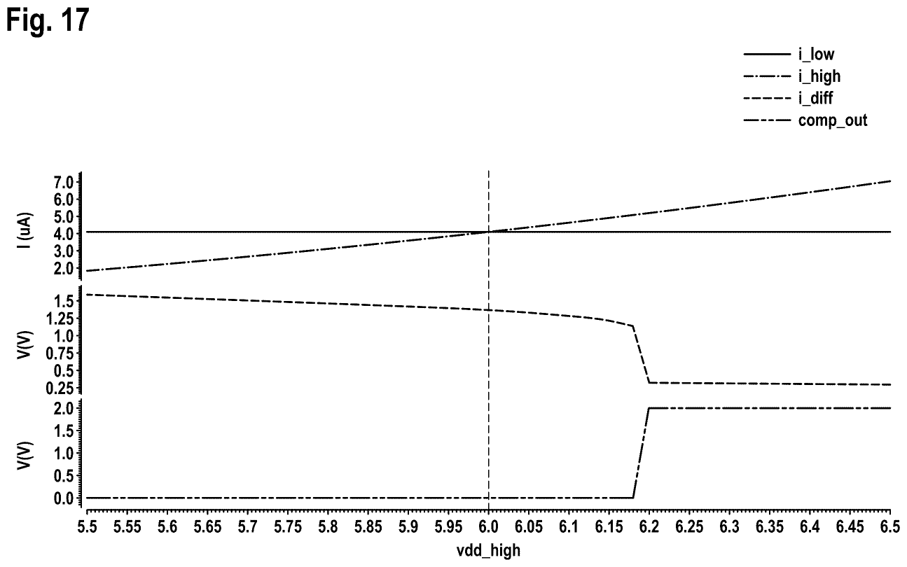

A second implementation variant for a current comparator is shown in FIG. 16. Two cross-coupled inverter stages are used here as well but, since the positions of P1 and N1 are not reversed, they form a proper latch. In this configuration, i_diff is not kept close to the switching threshold of the inverter. In terms of current consumption, this has the advantage that i_diff can move more freely in the direction of the Vdd_low/Vss_low supply rails and biases the inverters P1/N1 and P2/N2 in their respective ON and OFF states without allowing a direct current to flow between the supply rails. This behavior can also be seen in FIG. 17 for the network i_diff. This type of latch structure makes it possible to implement an internal hysteresis for the comp_out decision, which in this example is set at a threshold value between 6.15 V and 6.2 V compared to equal currents at 6 V. Such hysteresis can be useful to avoid unwanted ON/OFF switching (=comp_out) with respect to supply rail peaks and ripples and to make decisions only at stable rail voltages.

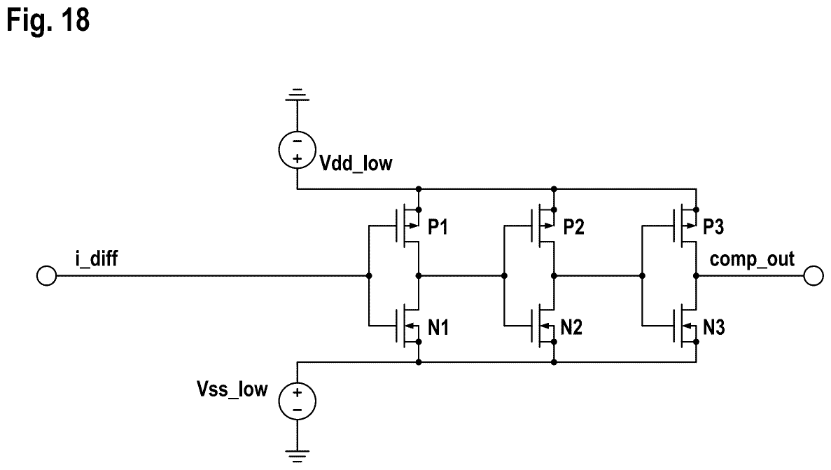

A current comparator can also be realized using a simpler implementation as is shown in FIG. 18. In the implementation according to FIG. 18, the potential at i_diff is directly connected to an input of the inverter with P1 and N1.

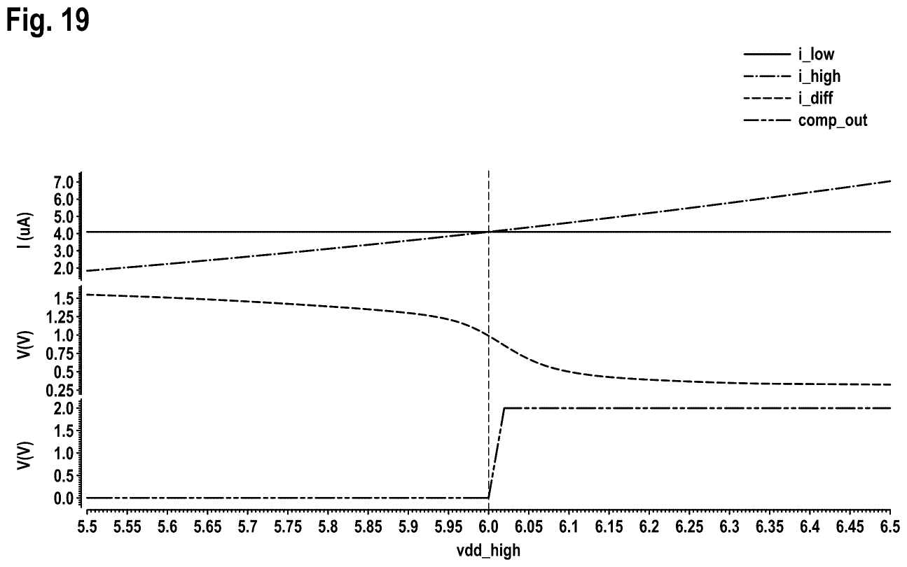

A comparison of FIG. 19 with FIG. 15 shows that the behavior of the current comparator according to FIG. 18 is similar to the behavior of the current comparator according to FIG. 14, but i_diff can move freely as is the case for the latch variant. Without the latch structure, there is no hysteresis in FIG. 19, and the signal comp_out begins to change its logical level as soon as i_high is greater than i_low.

What is claimed is:

1. A control circuit for a microelectromechanical sound generator with a first center connector, a second center connector, a first external connector and a second external connector, the control circuit comprising:
a differential amplifier which includes a first output connector coupled to the first external connector and a second output connector coupled to the second external connector, the differential amplifier being configured to control the first external connector and the second external connector with a differential signal that corresponds to an input signal;
a first voltage generator circuit configured to provide the first center connector with a predetermined first DC voltage in relation to a common-mode voltage of the differential amplifier; and
a second voltage generator circuit configured to provide the second center connector with a predetermined second DC voltage in relation to the common-mode voltage of the differential amplifier.

2. The control circuit according to claim 1, wherein the control circuit is configured to set a supply voltage for the differential amplifier as a function of a maximum amplitude of the input signal.

3. The control circuit according to claim 1, further comprising:
a level converter configured to adjust a common-mode signal level of the input signal, wherein the level converter is coupled to or integrated in the differential amplifier to provide an adjusted input signal.

4. The control circuit according to claim 3, wherein the control circuit is configured to receive a supply voltage for the level converter as a function of a maximum amplitude of the input signal.

5. The control circuit according to claim 1, wherein the control circuit is configured to receive an electrical voltage between a reference potential and a predetermined positive supply voltage as a supply voltage for the differential amplifier.

6. The control circuit according to claim 1, wherein the control circuit is configured to receive an electrical voltage between a predetermined negative supply voltage and a predetermined positive supply voltage as a supply voltage for the differential amplifier.

7. The control circuit according to claim 1, wherein the differential amplifier is a class G amplifier or a class H amplifier.

8. The control circuit according to claim 1, wherein:
the first voltage generator circuit provides the predetermined first DC voltage in relation to the common-mode voltage of the differential amplifier via a first buffer circuit, wherein the first buffer circuit uses two supply voltages, a voltage difference of the two supply voltages being kept constant by a first potential-free charge pump, using a first comparator which compares two currents, a first current of the two currents being proportional to the voltage difference and a second current of the two currents being proportional to a reference voltage; and/or
the second voltage generator circuit provides the predetermined second DC voltage in relation to the common-mode voltage of the differential amplifier via a second buffer circuit, wherein the second buffer circuit uses two supply voltages, a voltage difference of the two supply voltages being kept constant by a second potential-free charge pump, by using a second comparator which compares two currents, a first current of the two currents being proportional to the voltage difference, and a second current of the two currents being proportional to a reference voltage.

9. The control circuit according to claim 3, further comprising:
a signal processing device configured to receive a digital audio signal, convert the digital audio signal into an analog audio signal, and provide the analog audio signal as the input signal to the level converter or the differential amplifier, wherein the signal processing device is further configured to ascertain a maximum amplitude of the input signal using the digital input signal.

10. A microelectromechanical sound generator, comprising:
a first center connector, a second center connector, a first external connector, and a second external connector;
wherein the first external connector is disposed on a first substrate of the microelectromechanical sound generator and the second external connector is disposed on the first substrate; and
wherein the first center connector is disposed on a second substrate of the microelectromechanical sound generator and the second center connector is disposed on the second substrate.

11. The microelectromechanical sound generator according to claim 10, wherein:
the first substrate is configured to reduce a parasitic capacitance between the first external connector and the first substrate and a parasitic capacitance between the second external connector and the first substrate; and/or
wherein the second substrate is configured to increase a parasitic capacitance between the first center connector and the second substrate and a parasitic capacitance between the second center connector and the second substrate.

12. The microelectromechanical sound generator according to claim 10, wherein:
the first substrate is static and the second substrate is movable; or
the first substrate is movable and the second substrate is static.

13. A sound generation system, comprising:
a microelectromechanical sound generator, including:
a first center connector, a second center connector, a first external connector, and a second external connector,
wherein the first external connector is disposed on a first substrate of the microelectromechanical sound generator and the second external connector is disposed on the first substrate, and
wherein the first center connector is disposed on a second substrate of the microelectromechanical sound generator and the second center connector is disposed on the second substrate; and
a control circuit, including:
a differential amplifier which includes a first output connector coupled to the first external connector and a second output connector coupled to the second external connector, the differential amplifier being configured to control the first external connector and the second external connector with a differential signal that corresponds to an input signal,
a first voltage generator circuit configured to provide the first center connector with a predetermined first DC voltage in relation to a common-mode voltage of the differential amplifier, and
a second voltage generator circuit configured to provide the second center connector with a predetermined second DC voltage in relation to the common-mode voltage of the differential amplifier.
